(19) United States
(12) Patent Application Publication
(10) Pub. No.: US 2003/0076094 A1
(43) Pub. Date: Apr. 24, 2003

(54) Magnetic field detection device and magnetic field measurement apparatus

(75) Inventor: Shigeki Hoshino, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/263,196

(22) Filed: Oct. 3, 2002

(30) Foreign Application Priority Data
Oct. 18, 2001 (JP) 2001-321243

(51) Int. Cl. G01R 33/02

(52) U.S. Cl. 324/247; 324/252

(57) ABSTRACT

The intensity of magnetic field elements is measured in three-dimensional directions at a high speed without reducing spatial resolution. A magnetic field detection device 10 has a first loop wiring 1 for detection of a magnetic field element along an X-axis, a second loop wiring 2 for detection of a magnetic field element along a Y-axis and a third loop wiring 3 for detection of a magnetic field element along a Z-axis. These loop wirings are formed on a multilayer printed circuit board 4. The first loop wiring 1, the second loop wiring 2, and the third loop wiring 3 are preferably formed in such positions as to be orthogonal to each other.

### BACKGROUND OF THE INVENTION

1. Field of the Invention

The present invention relates to a magnetic field detection device and a magnetic field measurement apparatus, and, more particularly, to a three-dimensional magnetic field detection device which has three loop wirings in the same body, and to a magnetic field measurement apparatus using the three-dimensional magnetic field device.

2. Description of Related Art

When operating a circuit board having various electronic components including an MCM (multi-chip-module) mounted thereon, magnetic fields are generated by the electronic components. Such magnetic fields exert an undesired influence on surrounding electronic devices and may cause malfunction. There is a need to detect such magnetic fields and to measure the intensity of the magnetic fields, to cope with the adverse effect. A magnetic field detection device is used for this purpose. To measure the intensity of a magnetic field near to an electronic element with high accuracy by using a magnetic field detection device, it is necessary to measure the intensity of the magnetic field near to an electronic element along three different directions designated as an X-axis, a Y-axis and a Z-axis.

FIG. 8 is a schematic plan view of a conventional magnetic field detection device. This magnetic field detection device 50 is called a semi-rigid cable loop and has a semi-rigid cable 51 formed of a coaxial cable, and a loop 52 formed at an end of the semi-rigid cable 51, as shown in FIG. 8. Reference numeral 53 designates core wire. FIG. 9 is a schematic plan view of another conventional magnetic field detection device. This magnetic field detection device 55 is called a printed-circuit substrate type loop and has a loop 58 formed at an end of a wiring 57 formed on a printed-circuit substrate 56.

Each of the conventional magnetic field detection devices 50 and 55 shown in FIGS. 8 and 9 operates as a unidimensional magnetic field detection device for detecting a magnetic field along one direction, for example, one of the X-axis, Y-axis and Z-axis directions. Therefore, in the case of two-dimensional measurement, for example, X-axis and Y-axis, the magnetic field detection device 50 or 55 should be turned about the Z-axis by 90 degrees to measure the intensity of the magnetic field along the two axes, as shown in FIG. 10(a). In another case, it is necessary to use two magnetic field detection devices 50 or 55, thereby placing the two detection devices along the X-axis and Y-axis respectively, as shown in FIG. 10(b). Further, in the case of three-dimensional measurement, the magnetic field detection device 50 or 55 should be turned twice to detect three-dimensional magnetic field along the X-axis, Y-axis and Z-axis. In another case, it is necessary to use three magnetic field detection devices 50 or 55, thereby placing the three detection devices respectively along the X-axis, Y-axis and Z-axis.

### SUMMARY OF THE INVENTION

The conventional magnetic field detection devices have problems in the case of detection of two-dimensional or three-dimensional magnetic field, as described below.

As for a detection of two-dimensional magnetic field by using one magnetic field detection device 50 or 55, it is necessary to place the device 50 or 55 along X-axis and Y-axis, and to move the device from one place to the other place repeatedly with high accuracy. However, it takes a long time to place the device precisely and requires a complicated mechanism. Therefore, high-speed measurement cannot be achieved.

If two magnetic field detection devices 50 or 55 are used simultaneously, the two devices are placed along an X-axis and Y-axis. It is, however, difficult to improve spatial resolution since the two devices cannot be placed closely because of the devices' size.

As for detecting a three-dimensional magnetic field using only one magnetic field detection device 50 or 55, this requires an even more complicated mechanism and greater clearance than for measuring a two-dimensional magnetic field.

Therefore, to achieve a high-speed and highly accurate measurement of magnetic field elements in at least one direction, a simple operation using only one magnetic field detection device is needed.

The present invention relates to a magnetic field detection device which detects spatially-distributed magnetic field components in three dimensions, and relates to a magnetic field measurement apparatus which measures the intensity of magnetic field in three dimensions using the above-mentioned magnetic field detection device. The magnetic field detection device comprises a first loop wiring, a second loop wiring and a third loop wiring for detecting the magnetic field component, preferably along the X-axis, Y-axis and Z-axis.

The above-mentioned three loop wirings are formed in this same multilayer printed circuit board.

The invention thereby provides a magnetic field detection device and a magnetic field measurement apparatus which can measure the intensity of the magnetic field at high-speed without reducing the spatial resolution.

### BRIEF DESCRIPTION OF THE DRAWINGS

The above and other objects, features and advantages of the present invention will become more apparent from the following detailed description when taken in conjunction with the accompanying drawings wherein:

FIG. 1 is a diagram schematically showing a construction of a magnetic field detection device in a first embodiment of this invention;

FIG. 2(a) is a plan view showing part of a first wiring layer on a first insulating layer of a multilayer printed circuit board.

FIG. 2(b) is a plan view showing part of a second wiring layer on the other side of the first insulating layer;

FIG. 2(c) is a plan view showing part of a fourth layer wiring on a third insulating layer of a multilayer printed circuit board.

FIG. 3 is a cross-sectional view showing the construction of the magnetic field detection device along a lengthwise direction of the same;

FIG. 4(a) is a cross-sectional view showing the construction of a part of the magnetic field detection device;

FIG. 4(b) is a cross-sectional view showing the construction of a part of the magnetic field detection device;

FIG. 4(c) is a cross-sectional view showing the construction of a part of the magnetic field detection device;

FIG. 5 is a block diagram showing an arrangement of a magnetic field measurement apparatus which represents a second embodiment of this invention;

FIG. 6 is a block diagram showing an arrangement of a magnetic field measurement apparatus which represents a third embodiment of this invention;

FIG. 7(a) is a graph showing magnetic field measurement results obtained by a magnetic field measurement method of this invention;

FIG. 7(b) is a graph showing magnetic field measurement results obtained by a magnetic field measurement method of this invention;

FIG. 7(c) is a graph showing magnetic field measurement results obtained by a magnetic field measurement method of this invention;

FIG. 8 is a schematic plan view of a conventional magnetic field detection device;

FIG. 9 is a schematic plan view of a conventional magnetic field detection device;

FIG. 10(a) is a diagram schematically showing a method of detecting magnetic field elements in multi-dimension by using the conventional magnetic field detection device; and

FIG. 10(b) is a diagram schematically showing a method of detecting magnetic field elements in multi-dimension by using the conventional magnetic field detection device.

### DETAILED DESCRIPTION OF THE PREFERRED EMBODIMENTS

The present invention will now be described in detail below with reference to the accompanying drawings.

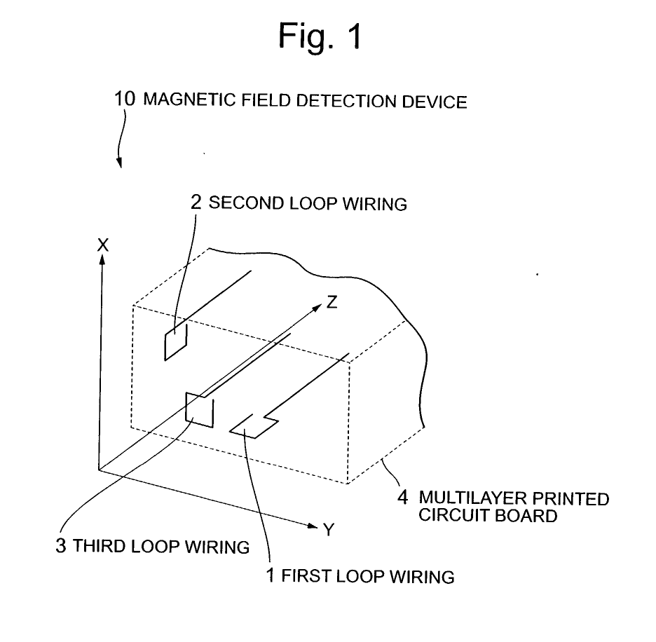

In the magnetic field detection device 10 of this embodiment, as shown in FIG. 1, there is formed a first loop wiring 1 for detection of a magnetic field component along an X-axis, a second loop wiring 2 for detection of a magnetic field component along a Y-axis, and a third loop wiring 3 for detection of a magnetic field component along a Z-axis, on a multilayer printed circuit board 4. The first loop wiring 1, the second loop wiring 2 and the third loop wiring 3 are preferably formed in such positions as to be orthogonal to each other.

Specifically, each of the first loop wiring 1, the second loop wiring 2 and the third loop wiring 3 comprises wiring formed by a conductive layer on an insulating layer, as described below.

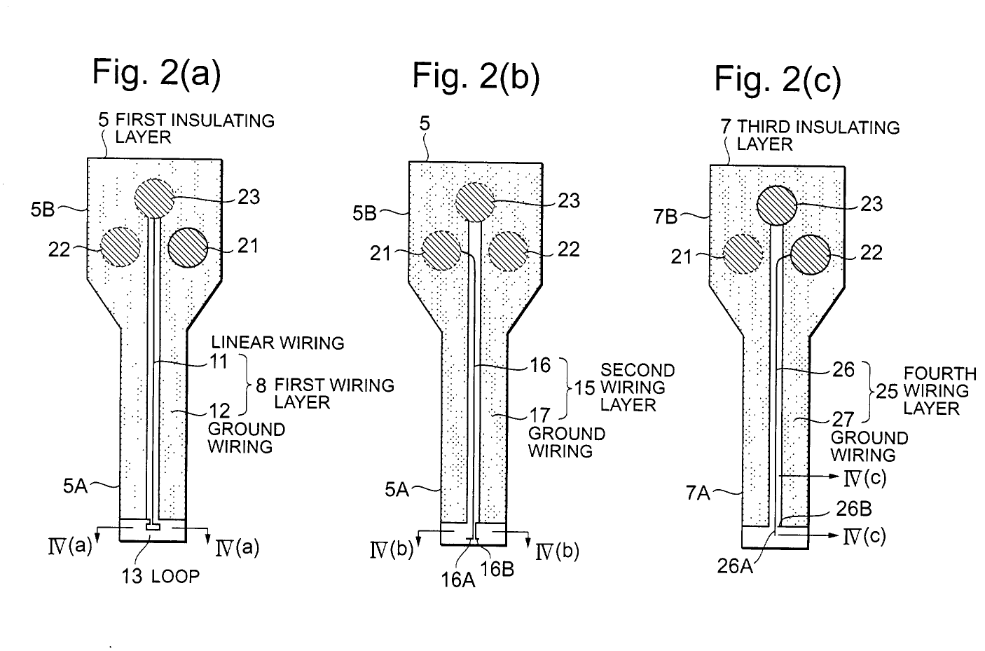

As shown in FIG. 2(a), a first wiring layer 8 which is-a planar wiring (a wiring formed into a planar shape on a surface of a first insulating layer 5) made of copper or the like is formed by printing on the surface of the first insulating layer 5. The multilayer circuit board is substantially rectangular with a narrower portion 5A and a wider portion 5B, as shown in FIG. 2(a), 2(b) and 2(c). This first wiring layer 8 comprises a linear wiring 11 formed substantially at a center of the surface of the first insulating layer 5 and a ground wiring 12 formed so as to surround the linear wiring 11. A loop 13 is formed at an end of the linear wiring 11. The end of the loop 13 is connected to the ground wiring 12.

The above-mentioned third loop wiring 3 comprises a linear wiring 11 and a loop 13 each of which is a piece of first layer wiring 8 formed on the surface of the first insulating layer 5. FIG. 4(a) shows the structure in a section along the line IV(a)-IV(a) in FIG. 2(a). For reference, a second insulating layer 6 and a third insulating layer 7 are drawn in FIG. 4(a). A connector 23 is connected to the linear wiring 11 forming a terminal of the third loop wiring 3, so as to form a coplanar type wiring structure. The position of the connector 23 is indicated schematically and is different from the position in the actual structure.

As shown in FIG. 2(b), a second wiring layer 15 which is a planar wiring made of copper or the like is formed by printing on a surface of a first insulating layer 5, which could also be substantially rectangular, with the portion 5A and the portion 5B having about the same width.

This second wiring layer 15 is constituted of a linear wiring 16 formed substantially at a center of a surface of the first insulating layer 5, and a ground wiring 17 formed so as to surround the linear wiring 16.

Wiring 16A and 16B comprising a portion of a loop 18 described below are formed at an end of the linear wiring 16. The wiring 16B is connected to the ground wiring 17.

A first insulating layer 5 has a first wiring layer 8 on one side and has a second insulating layer 6 on the other side from the first layer wiring 8.

A second insulating layer 6 has a second wiring layer 15 on the opposite side of the first insulating layer 5.

FIG. 4(b) shows the structure in a section along the line IV(b)-IV(b) in FIG. 2(b). For reference, a second insulating layer 6 and a third insulating layer 7 are drawn in FIG. 4(b). As is apparent from FIG. 4(b), on the first insulating layer 5 the second insulating layer 6 (not shown in FIG. 2) is formed and through hole wirings 19A and 19B connected to the wirings 16A and 16B are formed in the second insulating layer 6. A third wiring layer 20 which is a wiring made of copper or the like is formed by printing on the surface of the second insulating layer 6 as shown in FIG. 4(b). This third wiring layer 20 connects the through hole wirings 19A and 19B to each other.

The loop 18 is formed by the linear wirings 16A and 16B, through holes 19A and 19B, and a part of linear wiring of the third wiring layer 20 comprising the second wiring layer 15 formed on a surface of the first insulating layer 5, the third wiring layer 20 formed on the surface of the second insulating layer 6, and the through hole wirings 19A and 19B formed in the second insulating layer 6. A connector 21 is connected to the linear wiring 16 forming a terminal of the first loop wiring 1, to form a coplanar type wiring structure.

As shown in FIG. 2(c), a fourth wiring layer 25 which is a planar wiring made of copper or the like is formed by printing on the surface of a third insulating layer 7 (which, again, could also be substantially rectangular with portion 7A and portion 7B having about the same width). This fourth wiring layer 25 comprises a linear wiring 26 formed substantially at a center of the surface of the third insulating layer 7, and a ground wiring 27 formed so as to surround the linear wiring 26. Wiring elements 26A and 26B comprising a portion of a loop 28 described below are formed at an end of the linear wiring 26. The wiring 26B is connected to the ground wiring 27.

FIG. 4(c) shows the structure in a section along the line IV(c)-IV(c) in FIG. 2(c). For reference, a second insulating layer 6 and a third insulating layer 7 are drawn in FIG. 4(c). The third insulating layer 7 is formed on the second insulating layer 6 and through hole wirings 29A and 29B connected to the wiring 26 are formed in the third insulating layer 7. The third wiring layer 20 which is a planar wiring made of copper or the like is formed by printing on the surface of the second insulating layer 6. A part of wiring of the third wiring layer 20 connects the through hole wirings 29A and 29B to each other.

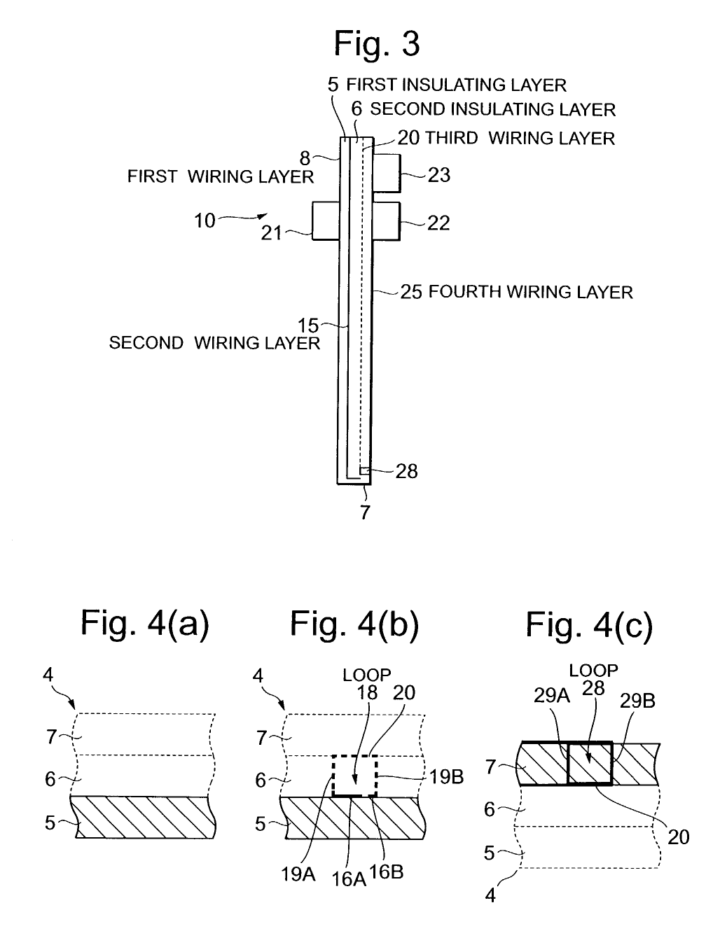

The loop 28 is formed by the linear wiring 26 comprising the fourth wiring layer 25 formed on the surface of the third insulating layer 7, the third layer wiring 20 formed on the surface of the second insulating layer 6, and the through hole wirings 29A and 29B formed in the third insulating layer 7. The above-mentioned second loop wiring 2 comprises this loop 28 and the linear wiring 26. A connector 22 is connected to the linear wiring 26 forming a terminal of the second loop wiring 2, so as to form a coplanar type wiring structure. FIG. 3 shows the structure in which the first layer wiring 8, the second wiring 15, the third wiring 20 and the fourth wiring 25 are laminated on the multilayer printed circuit board 4.

The first loop wiring 1, the second loop wiring 2 and the third loop wiring 3 comprising the magnetic field detection device 10 in this embodiment are formed so as to be substantially equal to each other in size. Also, an end portion of each of the loop wiring 1, the loop wiring 2 and the loop wiring 3 is connected in common to ground wiring. As the material for the first insulating layer 5, the second insulating layer 6 and the third insulating layer 7, a glass-epoxy composite, for example, is used. As the material for the first wiring layer 8, the second wiring layer 15, the third wiring layer 20 and the fourth wiring layer 25, copper, for example, is used and the wiring is formed to have a film thickness of 5 to 25 μm. Each of the linear wirings 11, 16 and 26 functioning as a signal wiring is formed so that its width is 0.1 to 0.2 mm. Each of the loops 13, 18, and 28 of the loop wiring 1, the loop wiring 2 and the loop wiring 3 is formed so that its opening area is (0.2 to 0.3) mm×(0.3 to 0.5) mm. The through hole for each of the through hole wirings 19A, 19B, 29A, and 29B is formed so that its diameter is 0.1 to 0.2 mm. The small-width and large-width portions of the magnetic field detection device 10 are formed so that the size of the small-width portions 5A and 7A is 4 to 6 mm, the size of the large-width portions 5B and 7B is 18 to 22 mm, and the size in the lengthwise direction X is 70 to 90 mm. The wiring structure of each of the loop wiring 1, the loop wiring 2, the loop wiring 3, the connector 21, the connector 22 and the connector 23 is set as a coplanar type having a characteristic impedance of about 50 Ω. It goes without saying that the above numerical parameters are by way of example only, and may vary considerably in practice.

In the magnetic field detection device 10 in this embodiment, the first loop wiring 1 for detection of a magnetic field along the X-axis, the second loop wiring 2 for detection of a magnetic field along the Y-axis, and the third loop wiring 3 for detection of a magnetic field along the Z-axis are formed on the multilayer printed circuit board 4 in such positions as to be orthogonal to each other. Therefore, when highly accurate measurement of the distribution of three-dimensional magnetic field is needed, only one magnetic field detection device is, used without the need for complicated control operations.

Consequently, it is possible to measure magnetic field elements in three dimensions at a high speed without reducing the spatial resolution.

Second Embodiment;

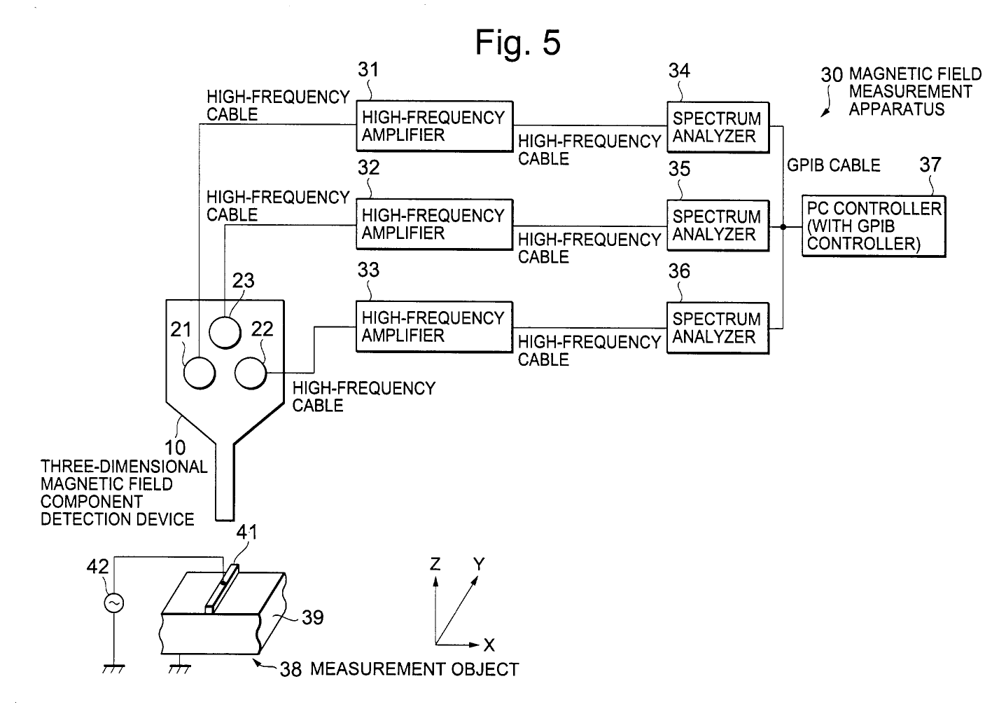

FIG. 5 is a block diagram showing the arrangement of a magnetic field measurement apparatus in a second embodiment of this invention. The magnetic field measurement apparatus of this embodiment includes the magnetic field detection device represented in, the first embodiment.

The magnetic field measurement apparatus 30 of this embodiment has, as shown in FIG. 5, the magnetic field detection device 10 of the first embodiment, in which the first loop wiring 1, the second loop wiring 2 and the third loop wiring 3 are formed in such positions on the multilayer printed circuit board 4 as to be orthogonal to each other; first, second and third high-frequency amplifiers 31-33 which are connected to the first, second and the third loop wirings 1-3, respectively, by high-frequency cables through connectors 21-23, and which amplify high-frequency signals based on magnetic field elements detected by the loop wirings 1-3, first, second and third spectrum analyzers 34-36 which are respectively connected to the first, second and third high-frequency amplifiers 31-33 by high-frequency cables, and which measure the magnetic field elements detected by the first, second and third loop wirings 1-3; and a PC (Personal Computer) controller (control means) 37 which performs operations for overall control (General Purpose-Interface Bus (GPIB) control) including control of the first, second, and third high-frequency amplifiers 31-33, and the first, second and the third spectrum analyzers 34-36.

The operation of these embodiments of the invention will now be described.

As a measurement object 38, a microstrip line wiring structure is prepared. A signal wiring 41 with film thickness about 20 μm and film width (a length along the X-axis) about 0.5 mm is formed on an insulating substrate 39. The magnetic field detection device 10 is placed close to this measurement object 38.

The magnetic field measurement apparatus 30 of this embodiment comprises the magnetic field detection device 10 of the first embodiment in which the three loop wirings are formed in such positions on the multilayer printed circuit board 4 as to be orthogonal to each other. Therefore, using the magnetic field measurement apparatus 30 can avoid the complicated procedure which consists of several steps to place one conventional magnetic field detection along each of the X-axis, Y-axis and Z-axis sequentially. Also, the magnetic field measurement apparatus 30 is much smaller than the conventional apparatus which has three separate magnetic field detection devices positioned in the X-axis, Y-axis and Z-axis respectively. Therefore the magnetic field measurement apparatus of this invention can be simplified.

A magnetic field measurement method using the magnetic field measurement apparatus 30 of this embodiment will be described below with reference to FIG. 5.

First, a high-frequency signal 42 (500 mV, 100 MHz) is input to the signal wiring 41 to generate a magnetic field as measurement object 38. To measure the distribution of the above described magnetic field in three dimensions, the magnetic field detection device 10 is moved along the X-axis.

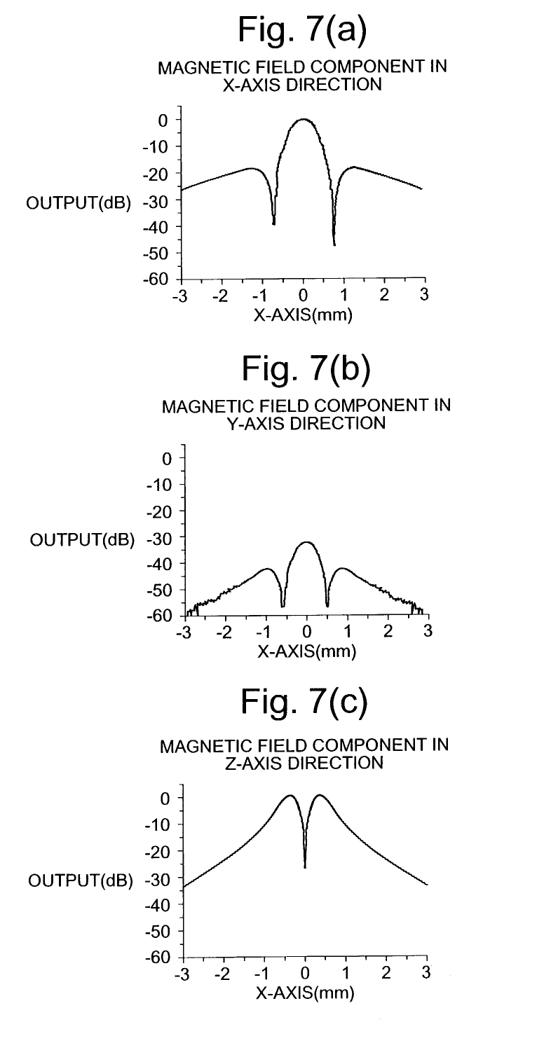

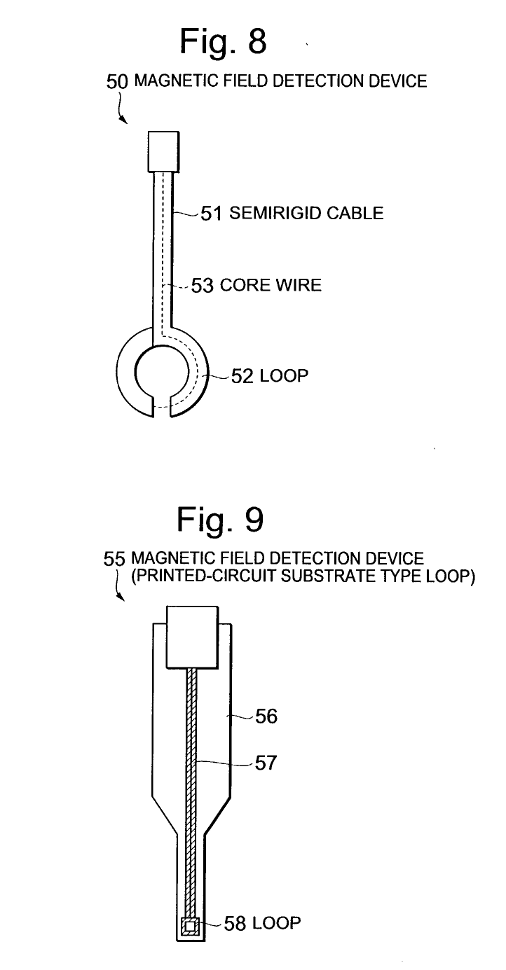

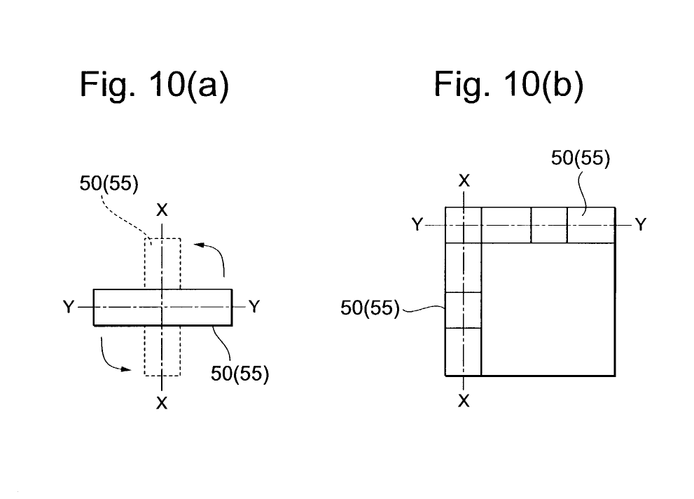

Under the control of the PC controller 37, high-frequency signals based on the distribution of the magnetic field detected by the first, second and third loop wirings 1-3 are input to amplifiers 31-33, respectively. The signals amplified by the first, second and third high-frequency amplifiers 31-33 are input to the first, second and third spectrum analyzers 34-36 to measure the intensity of the magnetic field elements in the three dimensional directions. Magnetic field measurement results such as those shown in FIGS. 7(a), 7(b) and 7(c) are thereby obtained.

FIG. 7(a) shows the intensity of magnetic field component Hx in the X-axis measured by the first loop wiring 1. Similarly, FIGS. 7(b) and 7(c) show the intensity of magnetic field components Hy and Hz in the Y-axis measured by the second loop wiring 2 and in the Z-axis measured by the third loop wiring 3, respectively. In FIGS. 7(a), 7(b) and 7(c), the ordinate represents the output of the spectrum analyzer and the abscissa represents the distance in the X-axis direction. The magnetic field measurement method of this embodiment can reduce the time for measurement to about 200 ms per position or shorter. In contrast, the conventional magnetic field measurement method requires separate measurements in each of the three-dimensional directions, so that a complicated control operation is required and thus the time taken is about one second or longer.

In the magnetic field measurement method of this embodiment, magnetic field measurement is performed by using the magnetic field detection device 10 of the first embodiment in which the first loop wiring 1 for detection of a magnetic field component along the X-axis direction, the second loop wiring 2 for detection of a magnetic field component along the Y-axis direction, and the third loop wiring 3 for detection of a magnetic field component along the Z-axis direction are formed in such positions on the multilayer printed circuit board 4 as to be orthogonal to each other. Thus, the magnitudes of magnetic field components in the three-dimensional directions can be simultaneously measured and this measurement can be performed at a high speed.

Third Embodiment

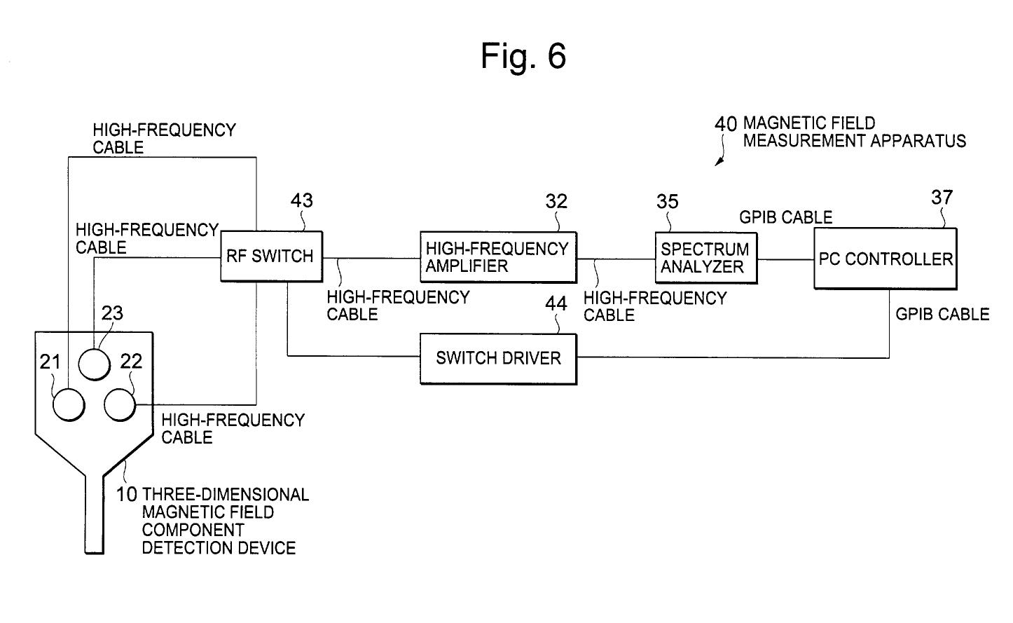

FIG. 6 is a block diagram showing the arrangement of a magnetic field measurement apparatus in a third embodiment of this invention. A difference between the third embodiment and the second embodiment resides in a set up enabling use of a common high-frequency amplifier and a common spectrum analyzer.

The magnetic field measurement apparatus 40 of the third embodiment has, as shown in FIG. 6, the magnetic field detection device 10 described in the first embodiment; a switch 43 which is connected to the first, second and third loop wirings 1-3 by high-frequency cables through connectors 21-23, and switch the signals detected by the first, second and third loop wirings 1-3; a switch driver 44 which controls the switching operation of the switch 43; a high-frequency amplifier 45 which is connected to the switch 43 by a high-frequency cable, and which amplifies each of the high-frequency signals based on magnetic field elements detected by the first, second and third loop wirings 1-3; a spectrum analyzer 46 which is connected to the high-frequency amplifier 45 by a high-frequency cable, and which measures each of the magnetic field elements detected by the first, second and third loop wirings 1-3; and a PC controller 37 which performs operations for overall control including control of the switch 43, the switch driver 44, the high-frequency amplifier 45 and the spectrum analyzer 46.

Thus, the magnetic field measurement apparatus 40 of this embodiment is arranged to use a common high-frequency amplifier 45 and a common spectrum analyzer 46 and therefore can be further simplified in structure in comparison with the magnetic field measurement apparatus 30 of the second embodiment.

A magnetic field measurement method using the magnetic field measurement apparatus 40 of this embodiment will be described below with reference to FIG. 6.

First, a high-frequency signal 42 (500 mV, 100 MHz) is input to a signal wiring 41 to generate a magnetic field as measurement object 38. To measure the distribution of the above described magnetic field in three dimensions, the magnetic field detection device 10 is moved along the X-axis, in a similar manner as the second embodiment.

Under the control of the PC controller 37, high-frequency signals based on the distribution of the magnetic field detected by the first, second and third loop wirings 1-3 are switched by the switch 43 and are amplified by the high-frequency amplifier 45. The amplified signals are input to the spectrum analyzer 46 to measure the intensity of the magnetic field components in the three dimensions. Magnetic field measurement results shown in FIG. 7(a), 7(b) and 7(c) are substantially similar to those obtained by the second embodiment.

The embodiments of this invention have been described in detail with reference to the drawings. However, possible specific arrangements of this invention are not limited to the above-described embodiments. For example, the number of wiring layers, the number of insulating layers, the type of wiring structure, the wiring film thickness, the wiring width, the opening area of the loops, the shape of the multilayer printed circuit board, etc. are by way of example only, and may vary considerably in practice.

The magnetic field detection device and magnetic field measurement apparatus according to present invention, the following effects can be obtained. That is, only one magnetic field detection device is needed to detect and measure an intensity of a magnetic field with high accuracy because the detection device of this invention comprises three loop wirings in the same multilayer printed circuit board.

Also, the construction of the magnetic field measurement apparatus of the present invention can be simplified by using the detection device of this invention.

Also, by using the magnetic field detection device of this invention, the magnetic field measurement in the three-dimensional directions can be simultaneously performed at a high speed without reducing the spatial resolution.

What is claimed is:

1. A magnetic field detection device which detects an intensity of magnetic field along three different directions, designated as an X-axis, a Y-axis, a Z-axis, comprising:
a first loop wiring for detecting a magnetic field intensity along said X-axis;
a second loop wiring for detecting a magnetic field intensity along said Y-axis;
a third loop wiring for detecting a magnetic field intensity along said Z-axis; and
a multilayer printed circuit board;
wherein said first loop, second loop and third loop are formed in said multilayer printed circuit board in such positions as to be perpendicular to said X, Y and Z axes, respectively.

2. The magnetic field detection device according to claim 1, wherein said X, Y and Z axes are orthogonal to one another.

3. The magnetic field detection device according to claim 1, wherein one of said three loop wirings is formed in a plurality of through holes in said multilayer printed circuit board.

4. The magnetic field detection device according to claim 1, wherein one of said three loop wirings is formed by a planar wiring on said multilayer printed circuit board and the other two loop wirings are formed in a plurality of through holes in said multilayer printed circuit board in such positions as to be orthogonal to each other.

5. The magnetic field detection device according to claim 1, wherein an end portion of each of said first, second and third loop wirings is connected to a ground wiring formed on said multilayer printed circuit board.

6. The magnetic field detection device according to claim 1, wherein said multilayer printed circuit board comprises at least three wiring layers.

7. The magnetic field detection device according to claim 1, further comprising:
at least one connector which connects said loops to at least one electronic element located outside said multilayer printed circuit board.

8. The magnetic field detection device according to claim 7, wherein each said connector is one of a coplanar type, a strip line type and a microstrip line type.

9. A magnetic field measurement apparatus which measures an intensity of magnetic field in three different directions, designated as an X-axis, a Y-axis, a Z-axis, comprising:
a magnetic field detection device according to claim 1;
an amplifier connected to at least one of said loop wirings;
a spectrum analyzer connected to said amplifier; and
control means for switching and performing said measurement.

10. The magnetic field measurement apparatus according to claim 9, wherein said amplifier is connect to all of said loop wirings.

11. The magnetic field measurement apparatus according to claim 9, further comprising two additional amplifiers, said amplifier and said two additional amplifiers each being connected to a respective one of said first, second and third loop wirings.
